(19) United States
(12) Patent Application Publication
(10) Pub. No.: US 2011/0019459 A1
(43) Pub. Date: Jan. 27, 2011

(54) Three-Dimensional Mask-Programmable Read-Only Memory with Reserved Space

(76) Inventor: Guobiao Zhang, Corvallis, OR (US)

Correspondence Address: GUOBIAO ZHANG, P.O. BOX 6182, STATELINE, NV, 89449-6182, US

(21) Appl. No.: 12/883,172

(22) Filed: Sep. 15, 2010

Related U.S. Application Data
(63) Continuation-in-part of application No. 11/736,773, filed on Apr. 18, 2007.
(60) Provisional application No. 60/884,618, filed on Jan. 11, 2007.

(51) Int. Cl. G11C 17/00

(52) U.S. Cl. 365/94

(57) ABSTRACT

The present invention discloses a three-dimensional mask-programmable read-only memory with reserved space (3D-MPROM_{RS}). It is released in a sequence of versions. In the original version, its storage space comprises an initial-release space and a reserved space. The initial-release space stores the multimedia files from the initial release. The reserved space, although large enough to store at least one multimedia file, does not store any file. In the later version, the reserved space stores the new release.

### CROSS-REFERENCE TO RELATED APPLICATIONS

This application is a continuation-in-part of U.S. patent application Ser. No. 11/736,773, “Mask-Programmable Memory with Reserved Space”, filed Apr. 18, 2007, which is related to a U.S. Patent Application Ser. No. 60/884,618, “Mask-Programmable Memory with Reserved Space”, filed Jan. 11, 2007.

### BACKGROUND

1. Technical Field of the Invention

The present invention relates to the field of integrated circuits, and more particularly to mask-programmable read-only memory.

2. Related Arts

For a mask-programmable read-only memory (i.e. mask-ROM), information is coded into info-mask and then written into the mask-ROM during manufacturing. The prior-art mask-ROM has a relatively high cost and every bit of its storage space is desired to be utilized. As illustrated in FIG. 1A, the storage space 5 of a prior-art mask-ROM is fully occupied by files 6a-6i. Little extra empty space exits, as is considered wasteful.

Mask-ROM is an ideal storage medium for multimedia contents. Multimedia contents could be textual files (e.g. books), audio files (e.g. songs, music), image files (e.g. photos, maps), video files (e.g. movies, video games), program files (e.g. for computers or mobile devices) and others. New multimedia contents are being constantly released. Because little extra empty space exits in the prior-art mask-ROM, each new multimedia release requires additional mask-ROM chip(s). For example, FIGS. 1B-1C illustrate the multimedia storage module 10 for the initial and second releases. In FIG. 1B, the multimedia storage module 10 comprises two mask-ROM chips 12a, 12b, which store multimedia files 6a-6r, 6j-6r from the initial release. In FIG. 1C, besides the mask-ROM chips 12a, 12b, the multimedia storage module 10 further comprises a new mask-ROM chip 12x. This new mask-ROM chip 12x stores the multimedia files 8x, 8y from the new release. This additional chip 12x requires re-design of the storage module, needs extra module footprint, and increases manufacturing costs. To overcome this and other drawbacks, the present invention discloses a three-dimensional mask-programmable read-only memory with reserved space (3D-MPROM_{RS}).

### OBJECTS AND ADVANTAGES

It is a principle object of the present invention to provide a mask-ROM that can easily accommodate new multimedia releases.

It is a further object of the present invention to provide a mask-ROM that can easily upgrade contents.

In accordance with these and other objects of the present invention, a three-dimensional mask-programmable read-only memory with reserved space (3D-MPROM_{RS}) is disclosed.

### SUMMARY OF THE INVENTION

With the advent of three-dimensional mask-programmable read-only memory (3D-MPROM) (referring to U.S. Pat. No. 5,835,396), the landscape of multimedia storage will forever change. Compared with prior-art mask-ROM, 3D-MPROM uses diode-like device as memory cell and vertically stacks multiple memory levels. Hence, it has much larger storage capacity and lower storage cost. In fact, its storage capacity becomes so large and its storage cost becomes so low that extra empty space in the 3D-MPROM is no longer considered wasteful. This is because the benefit brought by this empty space can outweigh the extra cost associated therewith: this empty space can be used to accommodate new multimedia release and therefore, simplify the design of the multimedia storage module and lower its overall cost. Accordingly, the present invention discloses a three-dimensional mask-programmable read-only memory with reserved space (3D-MPROM_{RS}).

The 3D-MPROM_{RS} is released in a sequence of versions. In the original version, its storage space comprises an initial-release space and a reserved space. The initial-release space stores the multimedia files from the initial release. The reserved space, although large enough for at least one multimedia file, does not store any file. The mask area corresponding to this reserved space is also reserved. It is either fully dark or fully clear. In the later version, the mask pattern corresponding to the new release is formed in the reserved mask area and therefore, the reserved space stores the new release.

### BRIEF DESCRIPTION OF THE DRAWINGS

FIG. 1A illustrates the storage space of a prior-art mask-ROM; FIG. 1B illustrates a prior-art multimedia storage module in its original version; FIG. 1C illustrates a prior-art multimedia storage module in its second version;

FIG. 2A illustrates a three-dimensional mask-programmable read-only memory (3D-MPROM); FIG. 2B illustrates the storage space of a preferred 3D-MPROM_{RS} for the initial release; FIG. 2C illustrates the storage space of the preferred 3D-MPROM_{RS} for the second release;

FIG. 3A is a cross-sectional view of a preferred three-dimensional mask-programmable read-only memory with reserved space (3D-MPROM_{RS}) in its original version;

FIG. 3B illustrates the corresponding mask pattern at memory level 400;

FIG. 4A is a cross-sectional view of the preferred 3D-MPROM_{RS} in its second version; FIG. 4B illustrates the corresponding mask pattern at memory level 400;

FIG. 5A is a cross-sectional view of a preferred 3D-MPROM_{RS} with a fully reserved memory level in its original version; FIG. 5B is a cross-sectional view of another preferred 3D-MPROM_{RS} with an absent memory level in its original version;

FIG. 6 is a cross-sectional view of the preferred 3D-MPROM_{RS} with a fully reserved memory level in its second version;

FIG. 7A illustrates a preferred 3D-MPROM-based three-dimensional memory module with reserved space (3D²-M²_{RS}) in its original version; FIG. 7B illustrates the preferred 3D²-M²_{RS} in its second version;

FIG. 8 illustrates a preferred method to upgrade contents stored in the 3D-MPROM_{RS}.

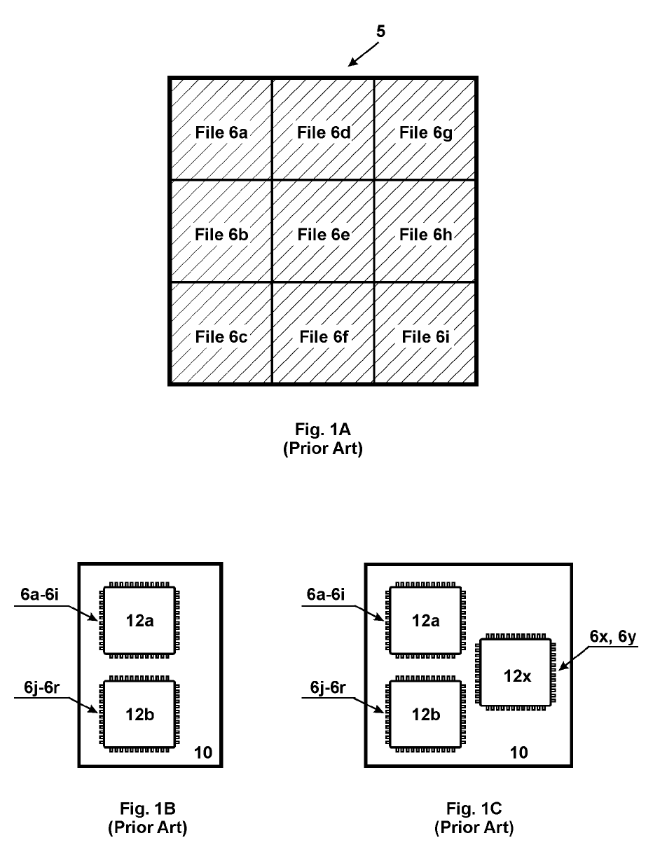

### DETAILED DESCRIPTION OF THE PREFERRED EMBODIMENTS

Those of ordinary skills in the art will realize that the following description of the present invention is illustrative only and is not intended to be in any way limiting. Other embodiments of the invention will readily suggest themselves to such skilled persons from an examination of the within disclosure.

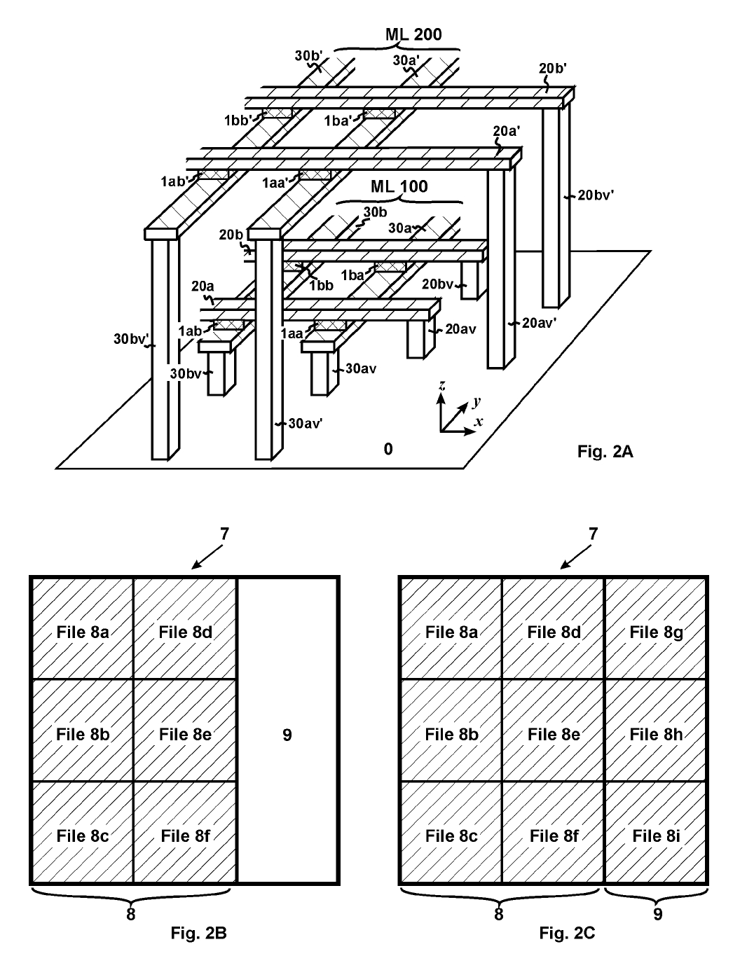

A three-dimensional mask-programmable read-only memory (3D-MPROM) comprises a plurality of memory levels vertically stacked above a semiconductor substrate. As illustrated in FIG. 2A, the two physical memory levels 100, 200 of the 3D-MPROM are stacked one by one on a semiconductor substrate 0. On each memory level (e.g. 100), there are a plurality of address-select lines (including word line 20a, 20b and bit line 30a, 30b) and mask-programmable read-only memory cells (1aa, 1ab, 1ba, 1bb . . . ). Substrate 0s comprises a plurality of transistors. These transistors function as peripheral circuits for the memory levels 100, 200. Contact vias (20av, 20av′, 30av, 30av′ . . . ) couple the memory levels (100, 200) with the peripheral circuit in the substrate. More details on 3D-MPROM can be found in U.S. Pat. Nos. 6,835,396, 6,717,222 and others.

With diode-based cell and stacked memory levels, 3D-MPROM has an extremely large capacity and an extremely low cost: at the 17 nm node, a 3D-MPROM chip could store ˜128 GB. A 3D-MPROM-based three-dimensional module (i.e. 3D²-M²) (referring to U.S. Patent Application 60/767,573) could store ˜1 TB. Furthermore, the storage cost of 3D-MPROM could be lowered to ˜ 1/10 of the prior-art mask-ROM.

With such a large capacity and low cost, 3D-MPROM is suitable for multimedia storage. More importantly, it can easily accommodate new multimedia release. Accordingly, the present invention discloses a three-dimensional mask-programmable read-only memory with reserved space (3D-MPROM_{RS}). It is released in a sequence of versions. In the original version, its storage space 7 comprises an initial-release space 8 and a reserved space 9 (FIG. 2B). The initial-release space 8 stores the multimedia files 8a-8f from the initial release. The reserved space 9, although large enough to store at least one multimedia file, does not store any file. In the later version, the reserved space 9 stores the multimedia files 8g-8i from the new release (FIG. 2C).

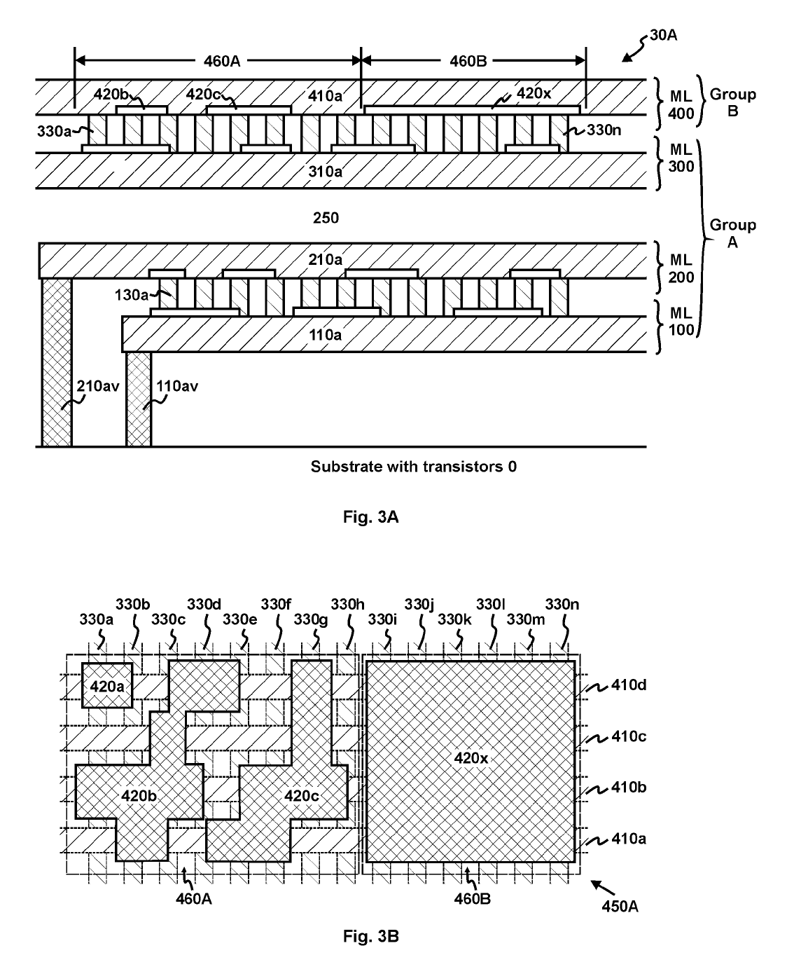

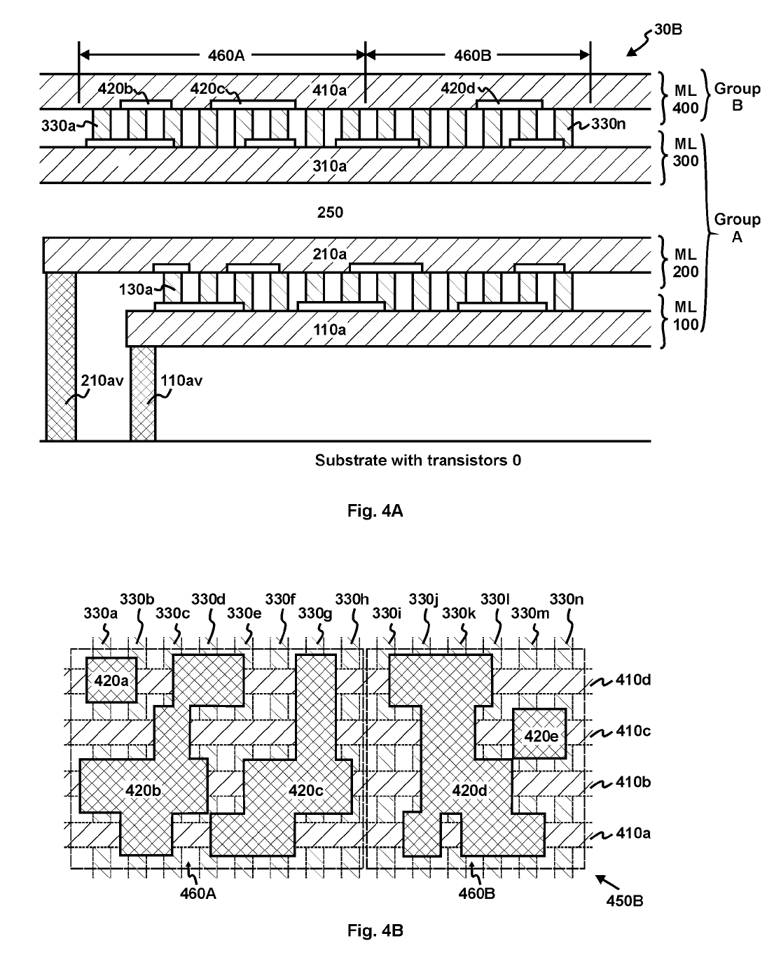

FIGS. 3A-4B illustrate a preferred 3D-MPROM_{RS} in its original version 30A and second version 30B. It comprises four vertically stacked mask-programmable read-only memory levels 100-400, which are further stacked above the substrate 0. Each memory level (e.g. 400) comprises word lines (e.g. 410a-410d), bit lines (e.g. 330a-330n) and info-dielectric (420a-420c, 420x). The patterns in the info-dielectric are transferred from the info-masks (e.g. 450A of FIG. 3B; or, 450B of FIG. 4B) and define the information stored in each memory cell: for a memory cell with no opening in the info-dielectric, it stores “0”; otherwise it stores “1”. Memory levels (e.g. 100, 200) are coupled to the substrate 0 by a plurality of contact vias (210av, 110av). For reason of simplicity, the contact vias for some memory levels (e.g. 300, 400) are not shown in these figures.

This preferred 3D-MPROM_{RS} (30A, 30B) uses a number of ways to increase storage capacity and lower manufacturing cost, including: 1) nF-opening (n>1), i.e. the dimension of the opening in the info-dielectric is larger than the width of the address line F (referring to U.S. Pat. No. 6,903,427); 2) N-ary 3D-MPROM (N>2), i.e. each 3D-MPROM cell has N states and stores more than one bit (referring to U.S. patent application Ser. No. 11/162,262); 3) hybrid-level 3D-MPROM, i.e. some memory levels share address lines (e.g. memory levels 200, 100 share address line 130a), while other memory levels do not (e.g. memory levels 300, 200 are separated by an inter-level dielectric 250) (referring to China, P.R. Patent Application 200610162698.2).

FIGS. 3A-3B are the cross-sectional view of 3D-MPROM_{RS} 30A in its original version and the corresponding mask pattern 450A at memory level 400. Here, the combined storage space formed by memory levels 100-300 and area 460A of memory level 400 is referred to as initial-release space. It stores the initial release of multimedia files. The storage space formed by area 460B of memory level 400 is referred to as reserved space. Although large enough to store at least one multimedia file, this reserved space does not store any file in the original version. The mask area 420x corresponding to this reserved space is also reserved. It is either all dark or all clear (FIG. 3B).

FIGS. 4A-4B are the cross-sectional view of 3D-MPROM_{RS} 30B in its second version and the corresponding mask pattern 450B at memory level 400. Here, the initial-release space remains the same, but the mask pattern 420d, 420e corresponding to new release is formed in area 460B (FIG. 4B). This means that new release is stored in the reserved space. Accordingly, this second-version 3D-MPROM_{RS} 30B carries not only the initial release, but also the new release (FIG. 4A). To lower the cost, all reserved mask areas are preferably consolidated into the least number of info-masks.

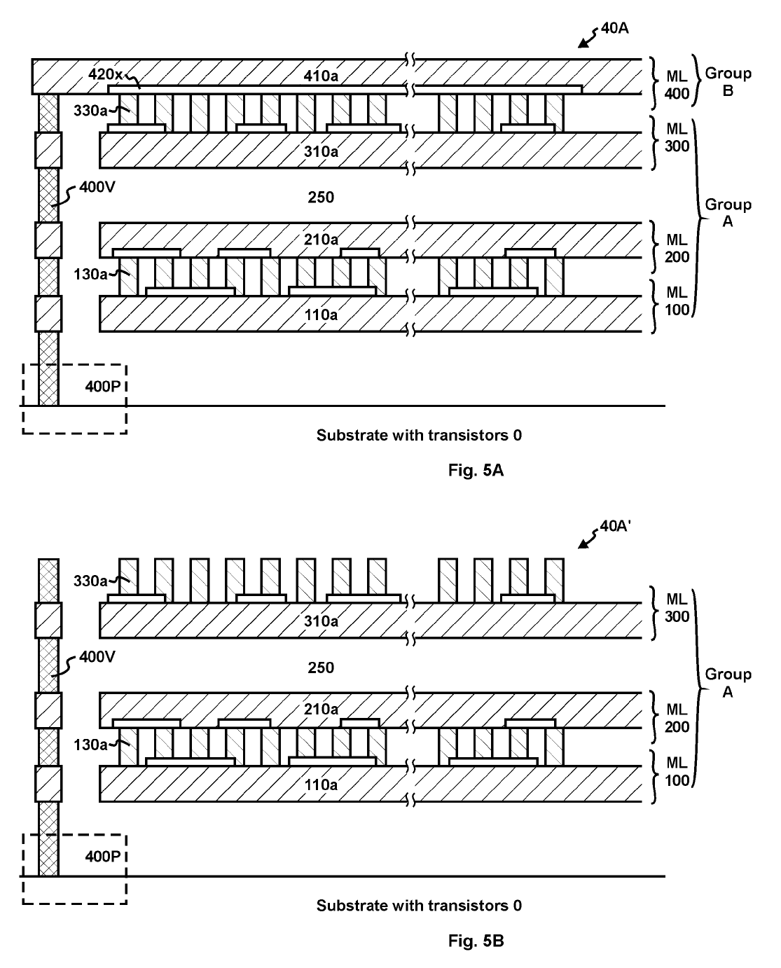

Besides reserving a partial memory level 460B for new release, the present invention further discloses a 3D-MPROM_{RS} with at least one fully reserved memory level. FIGS. 5A-5B illustrate two preferred 3D-MPROM_{RS}'s (40A, 40A′) with a fully reserved memory level (ML 400). They are in their original versions and designed to accommodate four memory levels 100-400. The combined storage space formed by memory levels 100-300 is the initial-release space, while the storage space formed by memory level 400 is the reserved space. Memory level 400 can take various forms. In FIG. 5A, memory level 400 is a dummy level, where all info-dielectric 420x in memory level 400 is intact, i.e. with no openings therein. In FIG. 5B, the memory level 400 is absent. However, in this preferred embodiment, some components for memory level 400 are still formed, e.g. its peripheral circuit 400P (in the substrate 0) and contact via 400V (which penetrates the dielectric layers of all lower memory levels 100-300 and can couple the memory level 400 to its peripheral circuit 400P). Apparently, the preferred 3D-MPROM_{RS} 40A′ in FIG. 5B has a lower manufacturing cost.

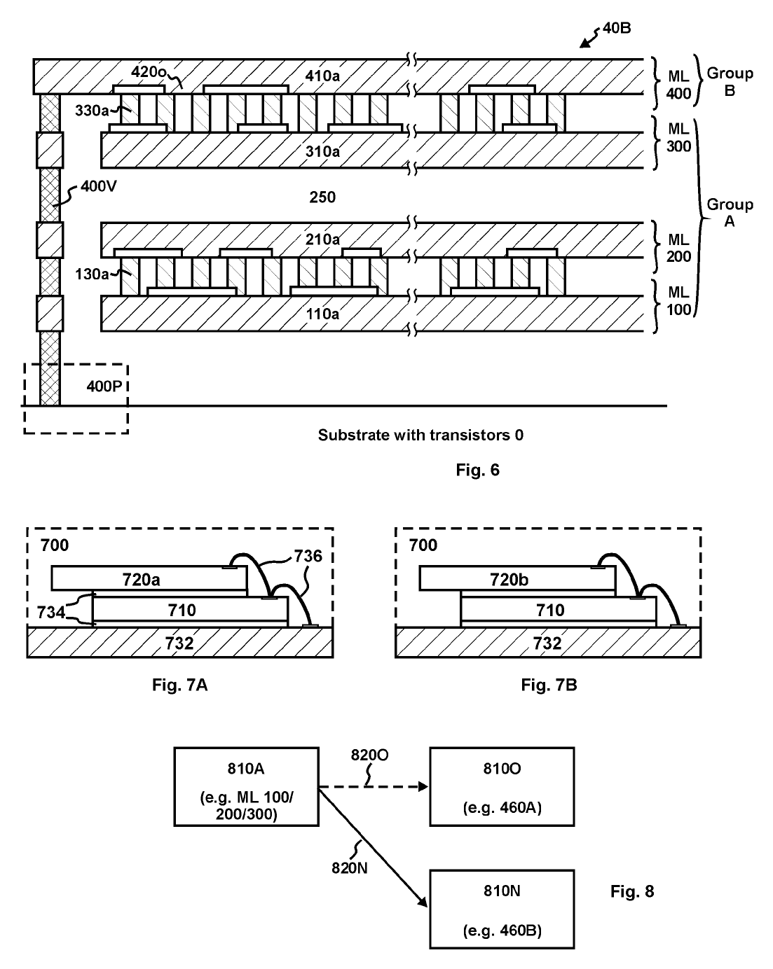

FIG. 6 illustrates the preferred 3D-MPROM_{RS} with a fully reserved memory level in its second version. Compared with FIGS. 5A-5B, openings 420o are formed at the selected locations of info-dielectric 420x in memory level 400. Moreover, word lines 410a are also formed for memory level 400. The resulting memory level 400 stores the new release of the multimedia files.

In the preferred embodiments of FIGS. 3A-6, the memory levels 100-400 can be categorized into two groups: Group A and Group B. Group A comprises memory levels without reserved space, e.g. memory levels 100-300; Group B comprises memory levels with reserved space, e.g. memory level 400. To achieve a fast turn-around time, Group B are preferably formed on top of Group A. In other words, the memory levels without reserved space are preferably fabricated before the memory levels with reserved space. In a mass-production environment, a large quantity of base wafers are pre-fabricated up to the highest memory level in Group A (i.e. without reserved space) (e.g. 300) and stockpiled. Once a new release of the multimedia files is available, only memory levels in Group B (i.e. with reserved space) (e.g. 400) need to be manufactured. Because only a small number of memory levels are involved, fast turn-around time can be achieved.

A three-dimensional memory module comprises a plurality of vertically stacked memory chips (referring to U.S. Patent Application 60/767,573). 3D-MPROM-based three-dimensional memory module (i.e. 3D²-M²) has an extremely large storage capacity (up to ˜1 TB) and is suitable for various multimedia libraries. The present invention further discloses a 3D²-M² with reserved space (3D²-M²_{RS}). It provides a storage medium with an extremely large capacity and an extremely low cost while still can easily accommodate new multimedia release.

FIG. 7A illustrates a preferred 3D²-M²_{RS} 700 in its original version. It comprises at least a 3D-MPROM_{RS} chip 720a in its original version and a second memory chip 710. The second memory chip 710 could be a conventional mask-ROM (i.e. without reserved space), another 3D-MPROM_{RS} or a read-write memory (RWM). RWM could be non-volatile memory such as flash memory. It can be used to store new release without replacing 3D-MPROM_{RS} 720a. These memory chips 720a, 710 are attached to each other by adhesive layer 734 and make electrical contact to each other and substrate 732 through bond wires 736. FIG. 7B illustrates the preferred 3D²-M²_{RS} in its second version. It comprises a 3D-MPROM_{RS} in its second version 720b and the second memory chip 710. New release is stored in the reserved space of the 3D-MPROM_{RS} 720b.

Besides adding new releases, 3D-MPROM_{RS} can also be used to upgrade contents. FIG. 8 illustrates a preferred upgrading means. In its original version, initial release comprises data 810A (stored in memory levels 100-300) and data 810O (stored in the area 460A of memory level 400). In its second version, data 810O becomes obsolete and needs to be replaced by new data 810N (e.g. software upgrade, map upgrade). This can be implemented by transferring the mask pattern corresponding to new data 810N to the reserved mask area 460B. Furthermore, 3D-MPROM_{RS} comprises a pointer. During upgrade, it changes from 820O to 820N, i.e. from pointing to obsolete data 810O to new data 810N.

While illustrative embodiments have been shown and described, it would be apparent to those skilled in the art that may more modifications than that have been mentioned above are possible without departing from the inventive concepts set forth therein. The invention, therefore, is not to be limited except in the spirit of the appended claims.

What is claimed is:

1. A three-dimensional mask-programmable read-only memory with reserved space, comprising a plurality of mask-programmable read-only memory levels vertically stacked above and coupled to a semiconductor substrate, wherein the storage space formed by said memory levels comprises:
an initial-release space, wherein said initial-release space stores a plurality of multimedia files; and
a reserved space, wherein said reserved space has a storage capacity large enough for at least one of said plurality of multimedia files but stores no file.

2. The three-dimensional mask-programmable read-only memory with reserved space according to claim 1, wherein said multimedia files include textual files.

3. The three-dimensional mask-programmable read-only memory with reserved space according to claim 1, wherein said multimedia files include audio files.

4. The three-dimensional mask-programmable read-only memory with reserved space according to claim 1, wherein said multimedia files include image files.

5. The three-dimensional mask-programmable read-only memory with reserved space according to claim 1, wherein said multimedia files include video files.

6. The three-dimensional mask-programmable read-only memory with reserved space according to claim 1, wherein said multimedia files include program files for computers or mobile devices.

7. The three-dimensional mask-programmable read-only memory with reserved space according to claim 1, wherein the info-masks for said memory levels comprise at least a reserved mask area associated with said reserved space.

8. A three-dimensional mask-programmable read-only memory with reserved space, comprising:
a semiconductor substrate;
a first group of memory levels stacked above and coupled to said semiconductor substrate, said first group comprising a plurality of vertically stacked mask-programmable read-only memory levels, wherein said first group stores a plurality of files; and
a second group of memory level stacked above said first group and coupled to said semiconductor substrate, said second group comprising at least one mask-programmable read-only memory level, wherein each memory level in said second group comprises a reserved space, wherein said reserved space has a storage capacity large enough for at least one of said plurality of files but stores no file.

9. The three-dimensional mask-programmable read-only memory with reserved space according to claim 8, wherein said files include multimedia files.

10. The three-dimensional mask-programmable read-only memory with reserved space according to claim 9, wherein said multimedia files include textual files, audio files, image files, video files and/or programs files.

11. A three-dimensional mask-programmable read-only memory with reserved space, comprising:
a semiconductor substrate;
a plurality of mask-programmable read-only memory levels stacked above and coupled to said semiconductor substrate; and
a plurality of contact vias through the dielectric layers of said plurality of mask-programmable read-only memory levels and coupled to said semiconductor substrate, wherein said contact vias are coupled to none of said plurality of mask-programmable read-only memory levels.

12. The three-dimensional mask-programmable read-only memory with reserved space according to claim 11, wherein said semiconductor substrate comprises a peripheral circuit coupled to said plurality of contact vias, said peripheral circuit working for none of said plurality of mask-programmable read-only memory levels.

13. The three-dimensional mask-programmable read-only memory with reserved space according to claim 11, wherein said plurality of mask-programmable read-only memory levels stores a plurality of files.

14. The three-dimensional mask-programmable read-only memory with reserved space according to claim 13, wherein said files include multimedia files.

15. The three-dimensional mask-programmable read-only memory with reserved space according to claim 14, wherein said multimedia files include textual files, audio files, image files, video files and/or programs files.
